(19) United States
(12) Patent Application Publication
(10) Pub. No.: US 2007/0133289 A1
(43) Pub. Date: Jun. 14, 2007

(54) NAND-type flash memory device with high voltage PMOS and embedded poly and methods of fabricating the same

(75) Inventors: Han-Rei Ma, Pudong New Area (CN); Fu-Chang Hsu, San Jose, CA (US); Peter Wung Lee, Saratoga, CA (US); Xiang Hong, Pudong New Area (CN)

Correspondence Address: STEPHEN B. ACKERMAN, 28 DAVIS AVENUE, POUGHKEEPSIE, NY, 12603, US

(73) Assignee: Aplus Flash Technology, Inc.

(21) Appl. No.: 11/606,535

(22) Filed: Nov. 30, 2006

Related U.S. Application Data
(60) Provisional application No. 60/742,021, filed on Dec. 1, 2005.

(51) Int. Cl. G11C 16/04

(52) U.S. Cl. 365/185.17

(57) ABSTRACT

The device of the invention includes a plurality of isolation layers formed at predetermined regions of a semiconductor substrate and running parallel with each other. The devices of the present invention also include a high voltage PMOS placed on top of a deep N-well and NMOS placed above a triple P-well inside the deep N-well in the peripheral area to pass both positive and negative high voltage of around +20V and −20V to the cell area. In one embodiment, the cell array, source lines and bit lines are all placed on top of the P-substrate without a deep N-well or Triple P-well. In other embodiments, the cell array, source lines and bit lines are placed on top of the deep N-well and triple P-well.

This application claims priority to U.S. Provisional Patent Application Ser. No. 60/742,021, filed on Dec. 01, 2005, which is herein incorporated by reference in its entirety.

### FIELD OF THE INVENTION

This invention relates to semiconductor memory devices and methods of fabricating the same and, more particularly, to NAND-type flash memory devices and methods of fabricating the same.

### BACKGROUND OF THE INVENTION

The NAND flash memory offers distinctive advantages compared to the other types of flash memories. By utilizing Fowler-Nordheim (FN) tunneling for program and erase operation, it has low current consumption and allows page-based program operation, which lead to good programming throughput. Another advantage is the small cell size, which can be attained by sharing a bit line (BL) contact between n NAND cell strings. The cells in a string connected in series have a simple source/drain structure, which leads to better scalability with relatively simple process technology.

A cell array region of the NAND-type flash memory device comprises a plurality of strings. The strings typically include a string selection transistor, a plurality of cell transistors and a ground selection transistor, which are serially connected. The drain region of the string selection transistor is connected to a bit line, and the source region of the ground selection transistor is connected to a source line.

An isolation layer defining a plurality of active regions is formed at a predetermined region of a semiconductor substrate. The active regions are defined in parallel to each other. A string selection line pattern, first to nth word line patterns WL0 to WLn-1, and a ground selection line pattern are formed across the isolation layer and the active regions. An impurity region formed at one side of the string selection line pattern acts as a drain region of the string selection transistor. Also, the impurity region formed at one side of the ground selection line pattern acts as a source region of the ground selection transistors.

Accordingly, the string selection transistor is formed in an area where the string selection line pattern and the active region intersect each other. Similarly, the ground selection transistor is formed in an area at which the ground selection line pattern and the active region intersect each other. The cell transistors are also formed in an area at which the word line patterns WL0 to WLn-1 and the active region intersect each other. As a result, a string is formed at each active region. Here, the string includes the string selection transistor, the cell transistor and the ground selection transistor that are serially connected.

Some related patents are U.S. Pat. No. 6,376,876 B1 to Shin et al and U.S. Pat. No. 6,577,533 B1 to Sakui et al.

In all the prior arts for NAND array, only +20V is provided to do both program and erase. Therefore, the cell array has to be placed on top of the triple P-well (TPW) inside the deep N-well (DNW) so that the positive high voltage can be applied to the TPW for erase operation. Also, the high voltage NMOS is placed above the P-substrate to reduce the processing steps. FIG. 21 is the cross section of a conventional NAND array which shows the array structure and its relationship with the peripheral high voltage devices. Cell array 35 is shown on top of the TPW 22 inside the DNW 11.

Since only bulk erase is allowed due to this TPW architecture, all the cells inside the TPW will be erased at the same time and this may cause over-erase for some cells. Then some of the cells will be over-programmed to compensate for the over-erased cells. This, in turn, will cause some difficulty for the read operation. Therefore, the real yield of the NAND cell suffers when the density becomes higher and higher due to the market trend. Furthermore, a very complicated file management and error correction mechanism becomes necessary.

As a result, it is desirable to use a different architecture to improve the yield and the reliability of the NAND memory devices.

### SUMMARY OF THE INVENTION

The main feature of the present invention is to provide a novel NAND array structure and architecture which can minimize the disturb issue and also improve the reliability of the NAND memory.

Another feature of the present invention is that the cell array can be placed on top of either the p-substrate or TPW by adding a high voltage PMOS device.

It is yet another feature of the present invention to provide a method of fabricating a NAND flash memory device which has better reliability and simplified design.

These and other features of the present invention may be provided by a NAND flash memory according to the invention.

The device of the invention includes a plurality of isolation layers formed at predetermined regions of a semiconductor substrate and running parallel with each other. The devices of the present invention also include a high voltage PMOS placed on top of a deep N-well and NMOS placed above a triple P-well inside the deep N-well in the peripheral area to pass both positive and negative high voltage of around +20V and −20V to the cell area.

In one embodiment, the cell array, source lines and bit lines are all placed on top of the P-substrate without deep N-well or Triple P-well. This will simplify the manufacturing process of the NAND memory devices and improve the reliability of the device.

In other embodiments, the cell array, source lines and bit lines will be placed on top of the deep N-well and triple P-well to be consistent with the conventional process.

In yet another embodiment, there is an additional poly layer to be embedded in the shallow trench area to simplify the program and inhibit operation.

### BRIEF DESCRIPTION OF THE DRAWINGS

The accompanying drawings are included to provide a further understanding of the invention, and so the features and advantages of the invention will be apparent. The drawings illustrate embodiments of the invention and, together with the description, serve to explain the principles of the invention.

FIG. 1 is a partial cross-sectional view of the first step of this new process to grow a thick oxide up to 400 Angstroms for high voltage NMOS and PMOS.

FIG. 2 is a partial cross-sectional view of the next few steps to do implants for deep N-well, triple P-well, low voltage P-well and N-well. The deep N-well and triple P-well are in the peripheral circuit and may or may not be placed in the cell array area.

FIG. 3 is a partial cross-sectional view to illustrate the threshold implant for high voltage NMOS in the triple P-well area.

FIG. 4 is a partial cross-sectional view to illustrate the threshold implant for high voltage PMOS in the deep N-well area.

FIG. 5 is a partial cross-sectional view of the implant operation of low voltage PMOS on top of the N-well.

FIG. 6 is a partial cross-sectional view of the implant operation of low voltage NMOS on top of the P-well.

FIG. 7 is a partial cross-sectional view of the implant operation of the flash cell for threshold adjustment. It can be implanted on top of the P-substrate, which is a special feature of the present invention, or it can be implanted on top of the triple P-well as in the conventional prior art.

FIG. 8 is a partial cross-sectional view of the wafer after growing tunnel oxide and poly 1. The poly 1 in the peripheral circuit is etched away and only remains in the cell area.

FIG. 9a to FIG. 9k illustrate one embodiment of the invention where an embedded poly is placed inside the STI trench for programming inhibit operation. In this process flow, the poly 1 will remain in the peripheral circuit to protect the gate oxide.

FIG. 9a is a partial cross-sectional view of the cell area after active area (AA) etch.

FIG. 9b is a partial cross-sectional view of the cell area with high density plasma (HDP) oxide deposited on the wafer.

FIG. 9c is a partial cross-sectional view of the cell area after the HDP oxide is partially etched away leaving a thin layer of oxide on the bottom.

FIG. 9d is a partial cross-sectional view of the cell area illustrating the gate oxide formed around the side wall and poly 1.

FIG. 9e is a partial cross-sectional area of the cell area to show the poly deposition step where the poly layer will be used for embedded poly.

FIG. 9f is a partial cross sectional area of the cell area to illustrate the poly etch step to leave the embedded poly in the bottom of the trench.

FIG. 9g is a partial cross-sectional area of the cell area illustrating the interpoly oxide deposition step after the embedded poly is formed.

FIG. 9h is a partial cross-sectional view of the cell area after the interpoly oxide is partially etched away and leaves some oxide on top of the embedded poly.

FIG. 9i is a cross-sectional area of the cell area illustrating the deposition of an ONO layer across the whole wafer. ONO and poly 1 will be etched away in the peripheral circuit before poly 2 deposition.

FIG. 9j is a partial cross-sectional view of the cell area after the deposition of the control poly layer poly 2 which also acts as the poly gate for peripheral devices.

FIG. 9k is a partial 3-dimensional diagram showing the cell structure after all poly steps are completed and one poly layer is embedded in the trench area for the sidewall transistor.

FIG. 10a is a partial cross-sectional view in section illustrating a self-aligned process. The poly 1 is patterned by an AA mask and forming the STI. This will prevent misalignment of Poly 1 with respect to the active area. This is one of the embodiments where no embedded poly is used and no sidewall transistor is formed.

FIG. 10b is a partial cross-sectional view in section illustrating the deposition of the oxide-Nitride-oxide layer on top of Poly 1 and acting as an insulation layer between the floating gate and the control gate. There is no Poly 1 on the peripheral circuit.

FIG. 11 is a partial cross-sectional view in section illustrating the deposition of the Poly 2 as the control gate. Poly 2 will be patterned in the cell area and the peripheral circuit with two different poly 2 masks to avoid process complexity.

FIG. 12 is a partial cross-sectional view illustrating the implantation of LDD for low voltage NMOS.

FIG. 13 is a partial cross-sectional view illustrating the implantation of LDD for low voltage PMOS.

FIG. 14 is a partial cross-sectional view illustrating the process of cell drain and source implant. It is mainly implanted in the cell area only and is adjusted for high breakdown voltage. Before the implant, the spacer will be formed to implement self-aligned SD implant.

FIG. 15 is a partial cross-sectional view illustrating the source and drain implant for high voltage NMOS. This is a DDD implant so that the breakdown voltage can be higher than 20 volts.

FIG. 16 is a partial cross-sectional view illustrating the implant step for high voltage PMOS. It is also a DDD implant so that the breakdown voltage must be lower than −20V.

FIG. 17 is a partial cross-sectional view illustrating the normal source/drain implant for a low voltage NMOS device.

FIG. 18 is a partial cross-sectional view illustrating the normal source/drain implant for a low voltage PMOS device.

FIGS. 19a b, and c are partial cross-sectional views illustrating the formation of silicide and drain/source contact. This contact will be connected to M1 through metal or poly plugs.

FIG. 19a shows the peripheral device, FIG. 19b shows the cell array on the triple P-well, and FIG. 19c shows the cell array on top of the P-substrate. The cell array in FIGS. 19b and 19c is the cross-sectional view from the bit line direction, perpendicular to the view in FIG. 19a.

FIGS. 20a, b, and c are total cross-sectional views of the process after three metal layers. FIGS. 20b and 20c show the cross-sectional view from the bit line direction, perpendicular to the view shown in FIG. 20a.

FIG. 21 is a cross-sectional view of the conventional NAND array to show that the cell array is on top of the triple P-well and there is no high voltage PMOS in the peripheral circuit. The high voltage NMOS is placed on top of the P-substrate.

### DETAILED DESCRIPTION OF THE PREFERRED EMBODIMENTS

In FIGS. 1-20, fabrication of a new NAND-type memory cell in a semiconductor wafer 10 is illustrated in accordance with one or more aspects of the invention, beginning with the formation of a thick oxide layer 20 for high voltage devices. Unlike the conventional prior art which only requires high voltage NMOS on top of the P-substrate, this invention will require high voltage NMOS on top of a triple P-well and high voltage PMOS on top of a deep N-well. The breakdown voltage for NMOS should be higher than +20V and for PMOS, the breakdown voltage must be less than −20V. In prior arts, the cell array must be placed on top of the triple P-well while this invention can use two approaches. In this invention, the cell array can be placed either on top of the P-substrate or on top of the triple P-well for flexibility.

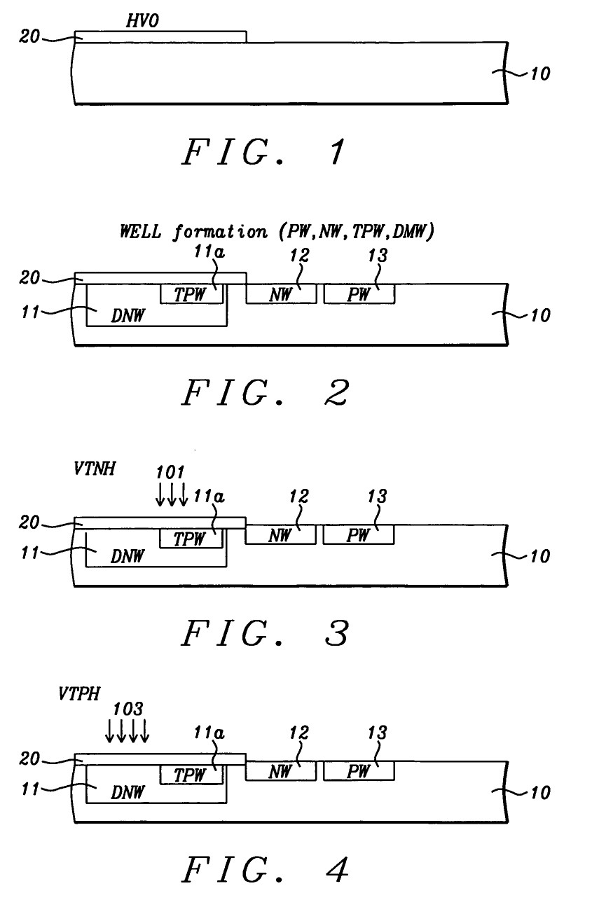

A thick thermal oxide of up to 400 Angstroms 20 is formed partially on the substrate 10 as shown in FIG. 1. Thereafter, a deep N-type well region 11 is formed in the P-type substrate 10 and a triple P-type well region Ha is formed inside the deep N-type well region 11. Forming the triple P-type well region includes implanting ions such as boron ions with an implantation of energy of about 50,000 volts. A normal N-type well 12 and a normal P-type well 13 are also formed. Then drive-in will be performed for all the dopants in the p-type well region and the n-type well region. Different wells will be driven to different depths. The deep N-well and triple P-well are in the peripheral circuit and may or may not be placed in the cell array area. After the well formation, the cross section of the wafer is shown as FIG. 2.

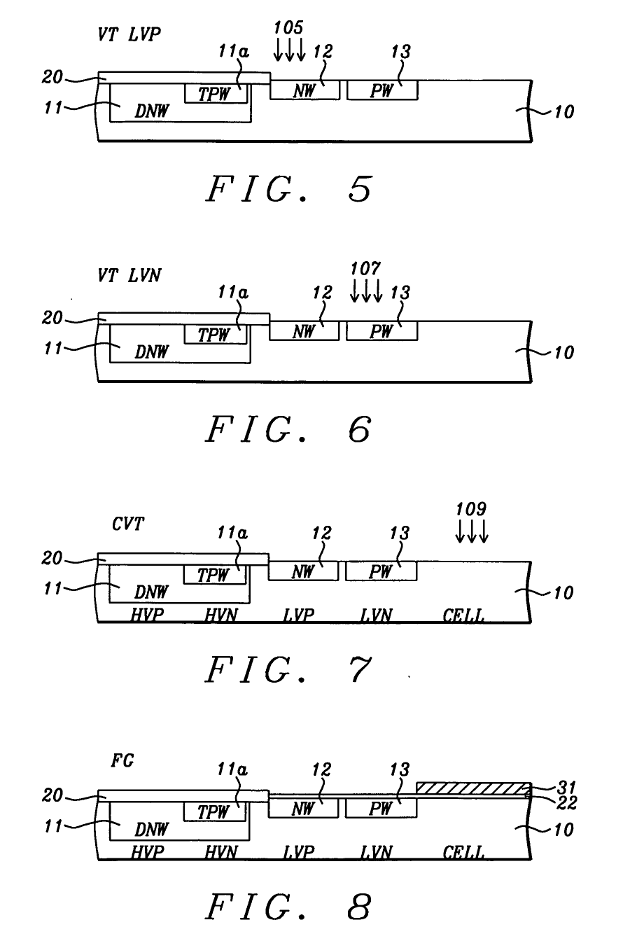

In FIG. 3, the threshold implant 101 for high voltage NMOS is done in the triple P-well area. The implant energy needs to be adjusted so that it will implant through the thick oxide 20. The threshold implant 103 for high voltage PMOS is then performed in the deep N-well area as shown in FIG. 4. The threshold implant 105 for low voltage PMOS on top of the N-well is performed in FIG. 5 and the threshold implant 107 for low voltage NMOS on top of the P-well is performed in FIG. 6. The implant operation 109 of flash cell for threshold adjustment is performed in FIG. 7 within the cell array region for the NAND-type flash memory. It can be implanted on top of the P-substrate 10, as shown in FIG. 7, which is a special feature of the present invention, or it can be implanted on top of the triple P-well 11a as in the conventional prior art, not shown.

Then the tunnel oxide 22 is grown over the entire wafer while the thick oxide 20 will also become thicker after this oxide growth. After the tunnel oxide growth, a conductive poly 1 layer 31 will be deposited across the whole wafer. This conductive layer includes a doped polysilicon type of material wherein this conductive layer is formed by performing a chemical vapor deposition to form an undoped polysilicon layer followed by performing an ion implantation process. Furthermore, this conductive layer is about 800˜1200 Angstroms thick. The poly 1 layer is patterned to leave the poly 1 layer 31 only in the cell array area, as shown in FIG. 8.

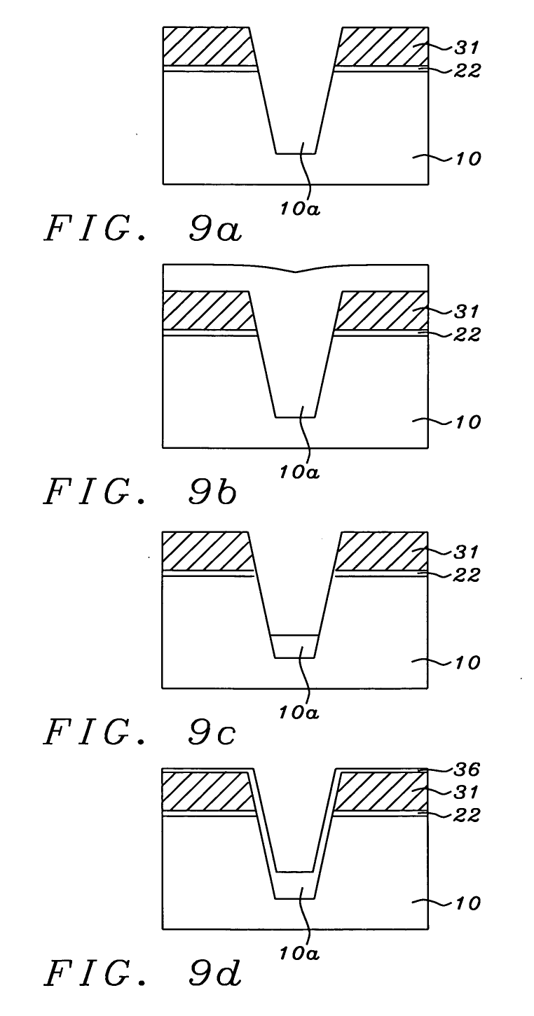

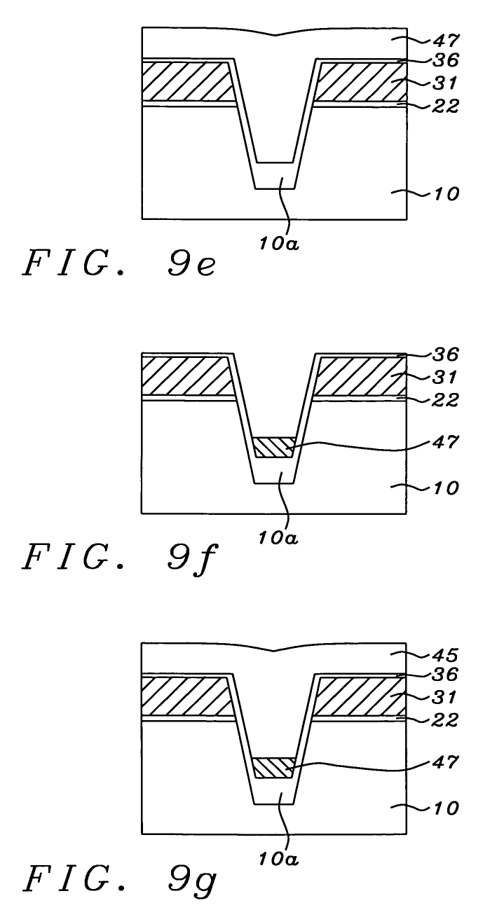

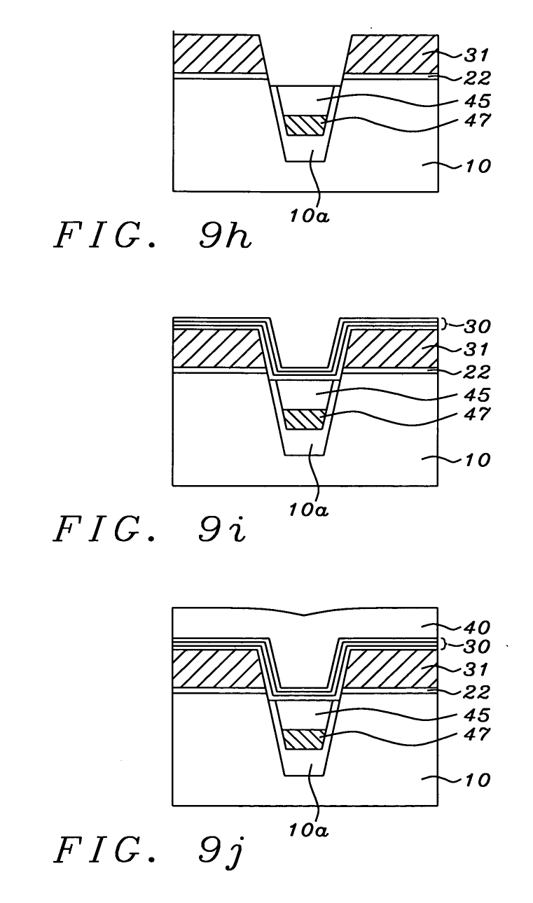

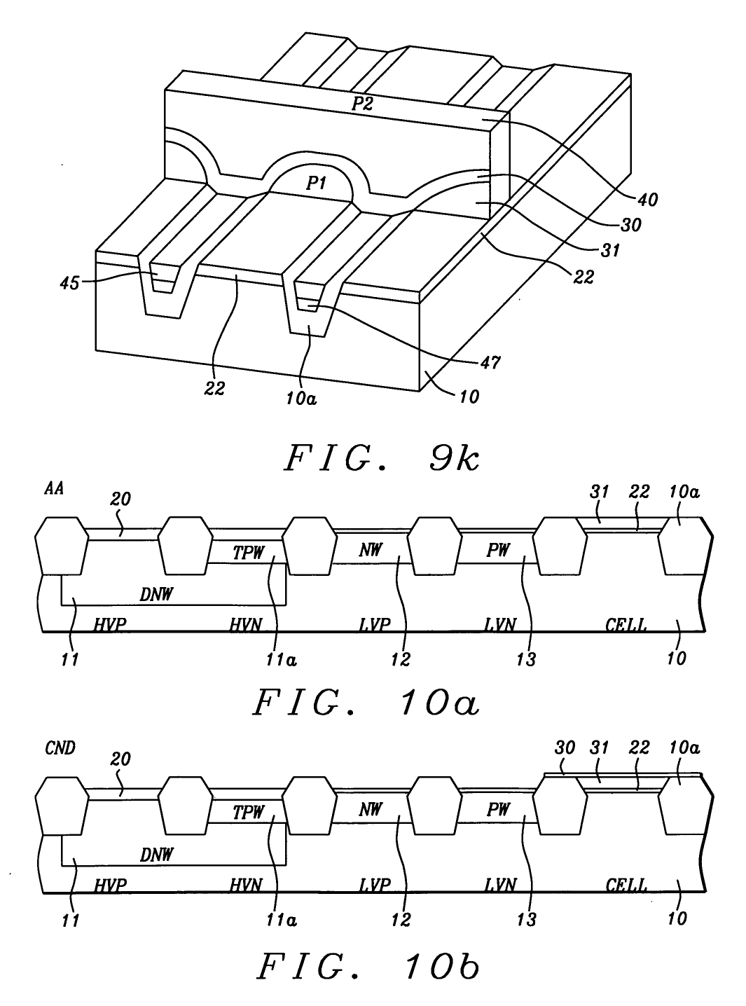

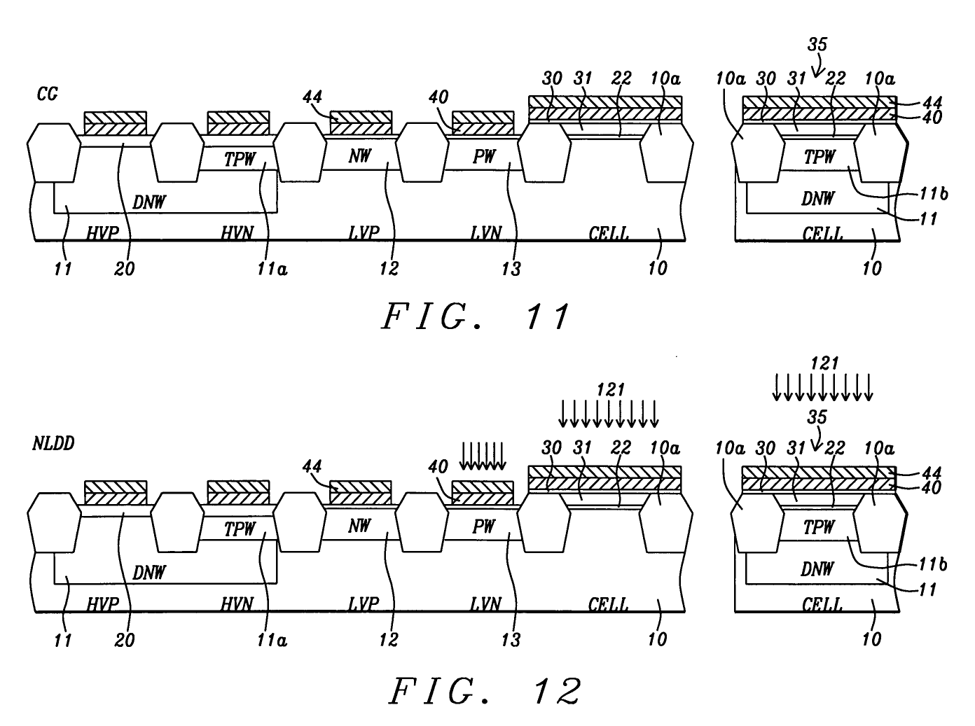

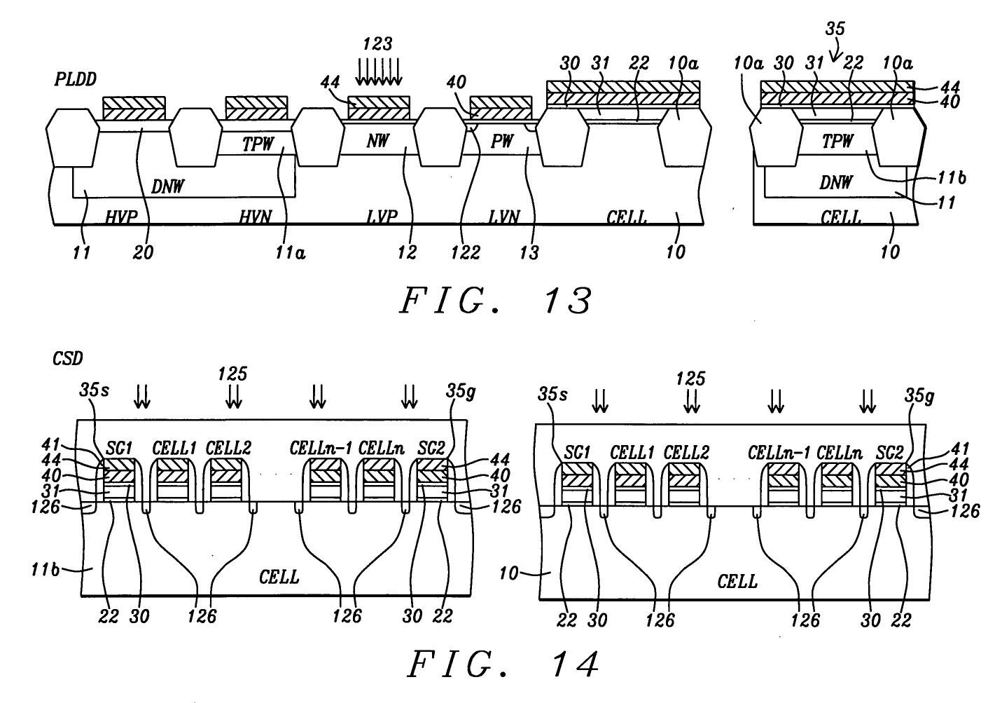

In one embodiment of the present invention, an embedded poly is placed inside the shallow trench as shown from FIG. 9a to FIG. 9j. In FIG. 9a, a trench 10a is formed in the cell area only. Treatment after trench etch is very critical to keep the surface of the sidewall in good condition since it will be used for the sidewall transistors. In FIG. 9b, the trench is filled by high density plasma (HDP) oxide. This oxide quality is important to withstand the high voltage of the word line during erase and program operation.

This HDP oxide will be etched away partially and leave a thick oxide in the bottom of the trench as shown in FIG. 9c. A side wall gate oxide 36 will then grow on the sidewall of the P-substrate and poly 1 for the side wall transistor as shown in FIG. 9d.

Deposition of embedded poly 47 as the gate for the sidewall transistor is then performed in FIG. 9e. The thickness of this poly is not critical since it is only used for programming of the flash cell. In FIG. 9f, all of the embedded poly is etched away outside the trench and only exists inside the trench to be used as the sidewall transistor. The operation principle of this sidewall transistor will be described in another patent.

In FIG. 9g, another HDP oxide 45 will be used to fill the trench on top of the embedded poly. At this point, the embedded poly process is complete. This new oxide film will be etched until it is lower than the tunnel oxide level as shown in FIG. 9h.

Oxide-Nitride-Oxide (ONO) insulation layer 30 is then deposited across the entire wafer in FIG. 9i. This is the major insulation between poly 1 and poly 2 for the flash cell and the PIP capacitor.

After the etch, all the ONO layer 30 in the peripheral circuit will be etched away, leaving ONO 30 only covering the poly 1 and cell area. Poly 2 layer 40 will then be deposited on the entire wafer, as shown in FIG. 9j. This poly 2 layer will be used for the control gate of the flash cell and the peripheral devices.

In FIG. 9k, a three dimensional diagram of the cell array with the embedded poly is depicted. It is shown clearly that the control poly 2 layer is used as the word line and is continuous across the poly 1 and embedded poly. Poly 1 is mainly used as the floating gate on top of the active area. The embedded poly can only be used as the sidewall transistor and is only used during programming operation. The embedded poly will be exposed and connected to outside voltage sources after 16 or 32 wordlines in series. FIG. 9k illustrates the cell area only and illustrates more than one cell unit.

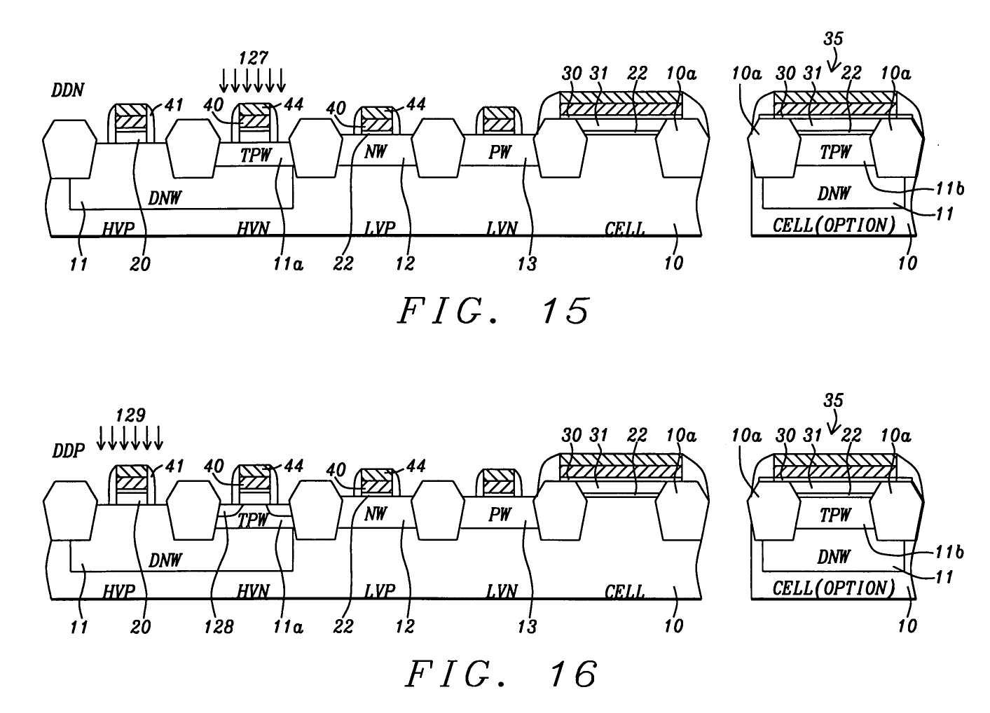

In another embodiment of this invention, embedded poly is not used as shown in FIG. 10a, where STI 10a will be formed after the poly 1 deposition. The poly 1 layer is patterned to form the conductive layer, exposing the isolation structures of the device. Then poly 1 is etched so that it only remains in the cell area while it is etched away in the peripheral circuit as shown in FIGS. 8 and 10a.

The AA mask is used to define the trench area. Since it is etched with poly 1 on top, the poly 1 is self-aligned with the active area and this will greatly improve the performance of the flash cell array. It is very critical to treat the tunnel oxide corner so that the leakage at the flash cell edge is controlled to a low level.

An isolation layer defining a plurality of active regions is formed at predetermined regions of the semiconductor substrate 10. The device isolation structures, such as shallow trench isolation (STI) regions 10a are arranged in stripes to define the active region, as shown in FIG. 10a.

The dielectric layer 30 includes a silicon oxide, silicon nitride, silicon oxide type of material that is then deposited on top of poly 1, as shown in FIG. 10b. The dielectric layer is formed by low pressure chemical vapor deposition. Then a conductive layer 40, like a doped polysilicon with a thickness of about 1500˜3000 Angstroms, will be deposited over the entire wafer surface. The conductive layer is formed by in-situ doped poly by means of chemical vapor deposition. For the polycide process, a cap layer 44 will be deposited on top of the poly 2 to prevent peeling of the tungsten films. The gate cap layer 44 includes material such as silicon nitride or silicon oxide. The gate cap layer is about 1000-1500 Angstroms thick and is formed by a method such as chemical vapor deposition.

Then the Poly 2 40 as control gate is formed in FIG. 11. It is the feature of this invention that the flash cell can be placed on top of either the P-substrate or the triple P-well. Drawing FIGS. 11, 12, 13, and 15-18 include the two options showing the flash cell 35 over the P-substrate in the main figure and over the triple P-well in the portion of the figure on the right hand side of the drawing.

As described above, an ONO layer 30, a conductive layer 40, and a cap layer 44 are sequentially formed on the substrate. Using a control gate mask, the cap layer 44 and the conductive layer 40 are patterned to define a gate cap layer and a conductive layer for the control gate. In other words, the stacked gate structure of the flash memory device is formed with the stacked structure of the gate cap layer 44, conductive layer (control gate) 40, the dielectric layer 30, the conductive layer (floating gate) 31, and the oxide layer (tunnel oxide layer) 22.

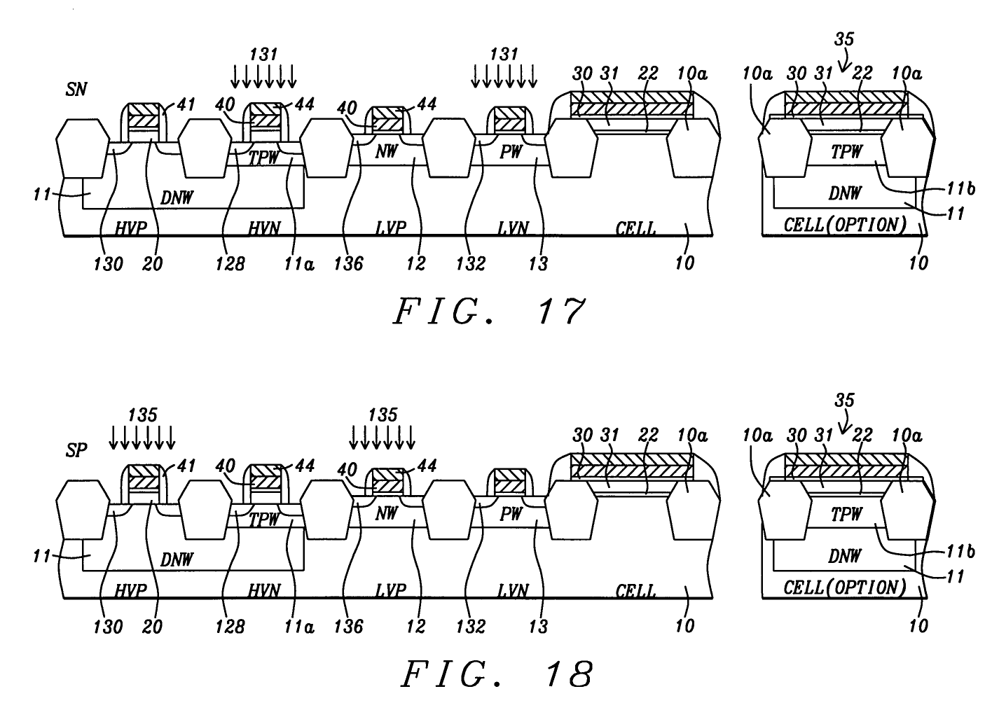

In FIG. 12, using the stacked gate structure to perform self aligned implantation, an ion implantation process is conducted to implant dopants into the substrate on the sides of the stacked gate structure and the low voltage NMOS devices to form the lightly doped source region and the drain region. The implanted dopants 121 include N-type dopants such as arsenic ions or phosphorous ions. To form the LDD source and drain region for the low voltage PMOS, a LDD implant 123 of Boron or BF₂ is performed in FIG. 13.

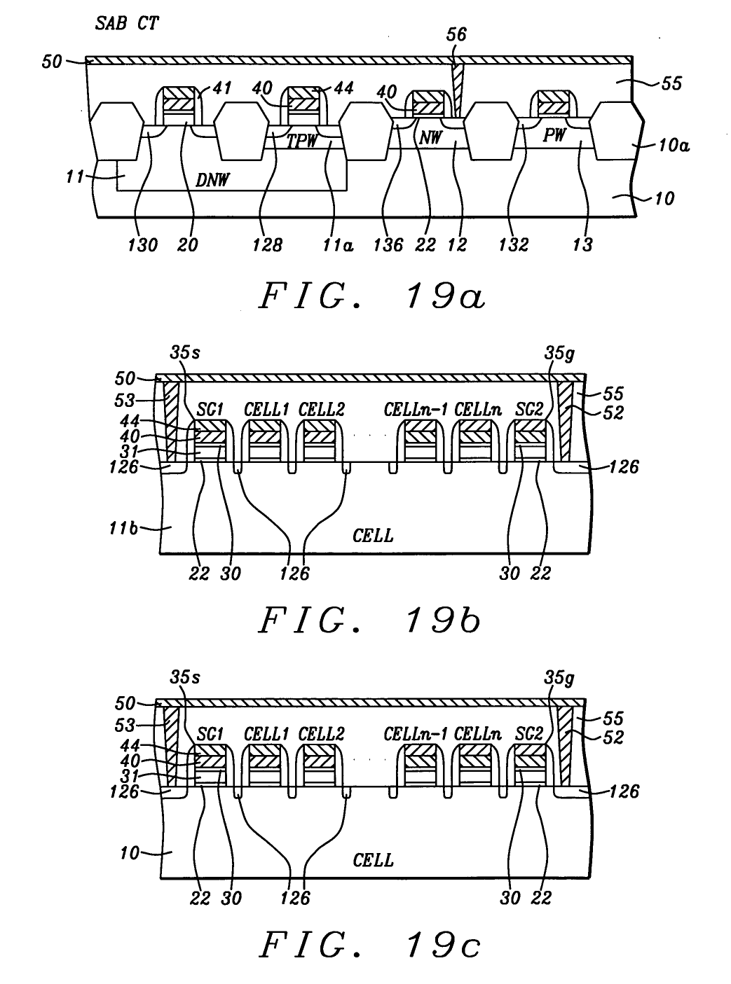

After the LDD implant, spacers 41 are formed on the sidewalls of the stacked gate structure. The spacers 41 are formed by forming an insulation layer such as a silicon nitride layer or a silicon oxide layer. This is followed by anisotropic etching to remove a portion of the insulation layer to form the spacers on the sidewall of the stacked gate structure. The spacers are illustrated in FIGS. 14 and 15. Then, more heavily doped cell source and drain implants will be performed to complete the implantation process for the cell area.

In FIG. 14, cell source and drain implant 125 of the flash cell area is performed. To illustrate the process clearly, a cross-sectional view of the wafer along the bit line direction is shown in the figure. Both options for the cell area are shown. On the left, the flash cell is overlying the TPW 11b. On the right, the flash cell is overlying the P-substrate 10. The implant atom has to reach the bottom of the spacer between the gate lines. Since the space is around 90 nm and the height of the gate is around 500 nm, it is important to do this implant at an angle of 90 degrees so that the ion will reach the bottom. Source and drain regions 126 are formed. These form the source lines and bit lines of the cell array. For example, for cell n, the area 126 to the left of the cell is the drain region of the cell n transistor and the area 126 to the right of the cell is the source region of the cell n transistor.

In FIG. 15, a double diffused implantation 127 is performed for high voltage NMOS on top of the triple P-well area to form source and drain regions 128. The dopant density should be chosen so that the junction breakdown voltage must exceed +20 volts. By the same token, a double diffused source drain implantation 129 for high voltage PMOS is performed in FIG. 16 to form source and drain regions 130. It is important that the junction breakdown voltage of this high voltage PMOS must be less than −20 volts.

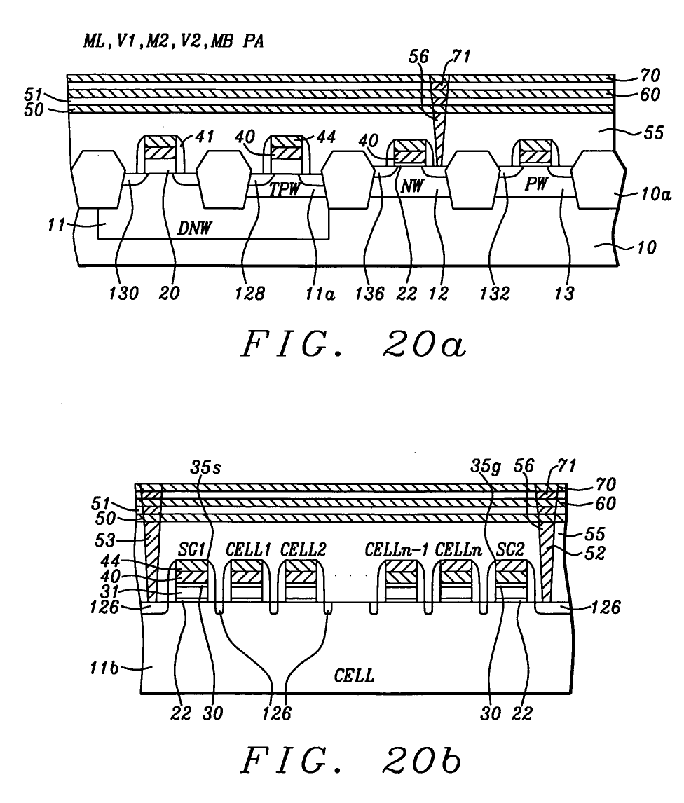

In FIG. 17, a normal source drain implant 131 is performed for low voltage NMOS on top of the P-well to form source and drain regions 132. It is usually implanted with low energy like 10 kV to get shallow junction depth for low voltage applications. This implantation 131 is also performed at high voltage NMOS on top of the triple P-well for the metal contact. For other applications, this implantation in the high voltage area can be replaced by the contact plug implant to the N+ contact only to reduce the transistor size.

The same principle can be applied to the normal source drain implant for low voltage PMOS as shown in FIG. 18, where the low voltage implant 135 is performed on top of the N-well to form source and drain regions 136 and the high voltage implant 135 is performed on top of the deep N-well. In the high voltage PMOS area, or P+ contact, an implant can also be used to reduce the transistor size.

After all the implantations, an interlayer dielectric layer 55 is formed on the entire wafer. This interlayer dielectric layer fills the aforementioned opening formed in the conductive layer. The interlayer dielectric layer includes BPSG and PSG by chemical vapor deposition. A chemical mechanical polishing is then conducted to planarize the surface of the interlayer dielectric layer.

A patterned photoresist layer is then formed on the entire substrate wherein this patterned photoresist layer exposes the drain and source regions. Thereafter, an etching process is performed to etch the substrate until drain and source regions are exposed, using the patterned photoresist layer and the stacked gate structure with the spacer as a mask. A contact 52, 53 is then formed above the source region and drain region between the gate structures and a contact 56 is also formed on the peripheral devices.

The contacts are then filled up with tungsten. After the tungsten formation, a metal conductive layer is either sputtered onto the entire wafer or electrically plated on the selective area, for example, a copper process. Aluminum is normally sputtered on the entire wafer while copper can be selectively plated or a single damascene and CMP process can be used to form the first metal layer 50 as shown in FIG. 19a. FIG. 19b shows the contact 53 in the cell area where it is formed close to the string selection transistor SG1 for the bit line 126 contact and the contact 52 in the cell area formed close to the ground selection transistor SG2 for source line 126 contact.

The bit line is a long line which consists of many drain and source regions 126 of the array transistors. The source line is a special line perpendicular to the bit line and is only connected to the contact 52 on one side of the transistor 35g. The bit line is connected to the metal 50 through contact 53. The bit line is parallel to the view in FIG. 19b and the source line 126 is perpendicular to the view and is under the contact metal 52.

It is also shown in FIG. 19b. that the array can be placed on top of the triple P-well 11b, like the conventional method. The array can be placed on top of the P-substrate 10 as a special feature of this invention, as shown in FIG. 19c.

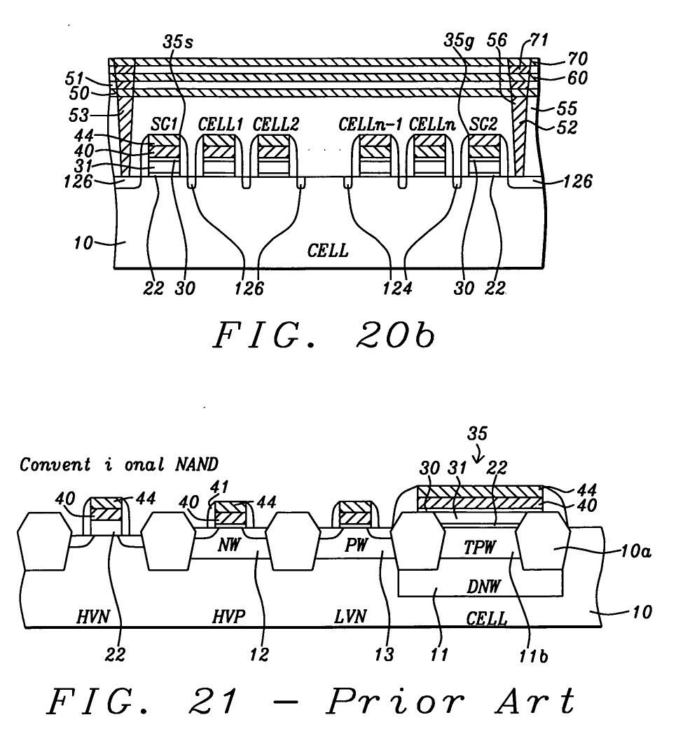

The subsequent manufacturing process is well known to those skilled in the art and will not be further reiterated here. The final cross sectional view of the wafer after the three metal layer process is shown in FIGS. 20a, 20b and 20c. FIG. 20a shows the peripheral areas. FIGS. 20b and 20c show two different cell area options, where the cell area is over the TPW 11b in FIG. 20b and where the cell area is over the P-substrate 10 in FIG. 20c. The views in FIGS. 20b and 20c are perpendicular to the view in FIG. 20a. Layer 51 forms the via 1, 60 is the metal 2 layer, 71 forms the via 2, and 70 is the metal 3 layer. Of course, more metal layers can be used when necessary.

The process of the present invention forms a novel NAND array structure and architecture which can minimize the disturb issue and also improve the reliability of the NAND memory. The cell array can be placed on top of either the p-substrate or the TPW by adding a high voltage PMOS device.

While the invention has been particularly shown and described with reference to preferred embodiments thereof, it will be understood by those skilled in the art that various changes in form and details may be made without departing from the spirit and scope of the invention.

What is claimed is:

1. A NAND-type flash memory device comprising:
a plurality of isolation regions formed at predetermined regions of a semiconductor substrate and running parallel with each other;
a high voltage PMOS component placed on top of a first deep N-well in a peripheral area of said substrate;
a high voltage NMOS component placed above a first triple P-well inside said first deep N-well; and
a flash memory cell array, source lines and bit lines in an active area of said substrate.

2. The device according to claim 1 wherein said flash memory cell array, source lines, and bit lines are placed on top of said substrate without an underlying N-well or P-well.

3. The device according to claim 1 wherein said flash memory cell array, source lines, and bit lines are placed on top of a second triple P-well in a second deep N-well.

4. The device according to claim 1 further comprising a low voltage NMOS component on a P-well in said peripheral area of said substrate.

5. The device according to claim 1 further comprising a low voltage PMOS component on an N-well in said peripheral area of said substrate.

6. The device according to claim 1 further comprising an additional poly layer embedded in a shallow trench only in said active area.

7. The device according to claim 6 wherein said additional poly layer is used as a sidewall transistor to simplify the program and inhibit operation.

8. The device according to claim 1 wherein each cell in said flash memory cell array comprises:
a gate cap layer;
a control gate underlying said gate cap layer;
a dielectric layer underlying said control gate;
a floating gate underlying said dielectric layer; and
a tunnel oxide layer underlying said floating gate.

9. The device according to claim 1 further comprising:
a dielectric layer covering said PMOS component, said NMOS component, and said flash memory cell array, said source lines, and said bit lines;
at least one metal line overlying said dielectric layer;
a first metal contact extending from said metal line and through said dielectric layer to one of said source lines in said active area;
a second metal contact extending from said metal line and through said dielectric layer to one of said bit lines in said active area; and
a third metal contact extending from said metal line and through said dielectric layer to a source or a drain region in said peripheral area.

10. A NAND-type flash memory device comprising:
a plurality of isolation regions formed at predetermined regions of a semiconductor substrate and running parallel with each other;
a high voltage PMOS component placed on top of a first deep N-well in a peripheral area of said substrate;
a high voltage NMOS component placed above a first triple P-well inside said first deep N-well; and
a flash memory cell array, source lines and bit lines in an active area of said substrate wherein said flash memory cell array, source lines, and bit lines are placed on top of said substrate without an underlying N-well or P-well.

11. The device according to claim 10 further comprising a low voltage NMOS component on a P-well in said peripheral area of said substrate.

12. The device according to claim 10 further comprising a low voltage PMOS component on an N-well in said peripheral area of said substrate.

13. The device according to claim 10 further comprising an additional poly layer embedded in a shallow trench.

14. The device according to claim 13 wherein said additional poly layer is used as a sidewall transistor to simplify the program and inhibit operation.

15. The device according to claim 10 wherein each cell in said flash memory cell array comprises:
a gate cap layer;
a control gate underlying said gate cap layer;
a dielectric layer underlying said control gate;
a floating gate underlying said dielectric layer; and
a tunnel oxide layer underlying said floating gate.

16. The device according to claim 10 further comprising:
a dielectric layer covering said PMOS component, said NMOS component, and said flash memory cell array, said source lines, and said bit lines;
at least one metal line overlying said dielectric layer;
a first metal contact extending from said metal line and through said dielectric layer to one of said source lines in said active area;
a second metal contact extending from said metal line and through said dielectric layer to one of said bit lines in said active area; and
a third metal contact extending from said metal line and through said dielectric layer to a source or a drain region in said peripheral area.

17. A method for fabricating a NAND-type flash memory device comprising:
forming a first deep N-well in a peripheral area of a substrate;
forming a first triple P-well inside a portion of said first deep N-well;
growing a thermal oxide layer over said peripheral area of said substrate and over a cell area of said substrate;
forming a first polysilicon layer over said cell area of said substrate;
forming a dielectric layer over said first polysilicon layer;
forming a second polysilicon layer over said dielectric layer and said thermal oxide layer;
forming a cap dielectric layer over said second polysilicon layer;
patterning said cap dielectric layer, said second polysilicon layer, and said thermal oxide layer in said peripheral area to form gate stacks;
patterning said cap dielectric layer, said second polysilicon layer, said dielectric layer, said first polysilicon layer, and said thermal oxide layer in said cell area to form a flash memory cell array;
forming source and drain regions in said substrate associated with said gate stacks and said flash memory cell array thereby forming said source lines and said bit lines;
forming an interlayer dielectric layer over said gate stacks and said flash memory cell array;
forming a first metal contact extending through said interlevel dielectric layer to a source region in said memory cell area;
forming a second metal contact extending through said interlevel dielectric layer to a drain region in said memory cell area;
forming a third metal contact extending through said interlevel dielectric layer to a source or a drain region in said peripheral area; and
forming at least one metal layer overlying said interlevel dielectric layer and connecting to said first, second, and third metal contacts.

18. The method according to claim 17 further comprising forming said flash memory cell array on top of said substrate without an underlying N-well or P-well.

19. The device according to claim 17 further comprising forming said flash memory cell array on top a second triple P-well in a second deep N-well.

20. The device according to claim 17 wherein said gate stack on top of said first deep N-well in a peripheral area of said substrate comprises a high voltage PMOS component and wherein said gate stack on top of said first triple P-well inside said first deep N-well comprises a high voltage NMOS component.
